(19) United States
(12) Patent Application Publication
(10) Pub. No.: US 2015/0376438 A1
(43) Pub. Date: Dec. 31, 2015

(54) COMPOUNDERS FOR ENHANCING GENERATION OF CHEMICAL SPECIES

(71) Applicant: TOYO GOSEI CO., LTD., Chiba (JP)

(72) Inventors: Satoshi Enomoto, Chiba (JP); Yusuke Suga, Chiba (JP); Takumi Yoshino, Chiba (JP)

(73) Assignee: TOYO GOSEI CO., LTD., Chiba (JP)

(21) Appl. No.: 14/750,689

(22) Filed: Jun. 25, 2015

Related U.S. Application Data
(60) Provisional application No. 62/017,756, filed on Jun. 26, 2014.

(51) Int. Cl. C09D 133/14; H01L 21/67; H01L 21/02

(52) U.S. Cl. CPC C09D 133/14; H01L 21/02118; H01L 21/02282; H01L 21/02348; H01L 21/67115

(57) ABSTRACT

A reagent that enhances acid generation of a photoacid generator and composition containing such reagent is disclosed.

### CROSS-REFERENCE TO RELATED APPLICATION

This application claims the benefit under 35 U.S.C. §119(e) of U.S. Provisional Patent Application Ser. No. 62/017,756 filed on Jun. 26, 2014, the disclosure of which is hereby incorporated herein in its entirety by this reference.

### TECHNICAL FIELD

Several aspects of the present invention relates to the fields of compounders enhancing a generation of a chemical species such as acid and base. Typical examples of compounders relating to an aspect of the present invention can be used as constituent of photoresist compositions which can be applied to fabrication of interlayer insulating films of devices such as liquid crystal display (LCD), organic electroluminescent display (OLED) and semiconductor device. More typical examples of such compounders relating to an aspect of the present invention are those which can be excited by absorbing a light of which wavelength is in a range from 200 nm to 400 nm and donate energy or an electron to a photoacid generator (PAG) contained in photoresist so that the PAG generates acid.

### BACKGROUND

Current high-resolution lithographic processes are based on chemically amplified resists (CARs) and are used to pattern features with fine dimensions.

Method for forming pattern features with fine dimensions is disclosed in U.S. Pat. No. 7,851,252 (filed on Feb. 17, 2009).

### BRIEF SUMMARY

A compounder relating to an aspect of the present invention is characterized by that: the compounder absorbs a light of which wavelength is longer than 220 nm; and the compounder is capable of sensitizing a precursor to generate a chemical species from the precursor.

With regard to the compounder, it is preferred that the compounder has at least one aromatic ring.

With regard to the compounder, it is preferred that the compounder has at least one electron-donating group on such aromatic ring. Typical examples of such electron-donating group are alkoxy group, aryloxy group, amino group having at least one alkyl or aryl group on the nitrogen group, alkylthio group, arylthio group and trialkylsilylmethyl group. More preferable examples are alkoxy group such as methoxy group and alkylthio group such as methylthio group.

With regard to the compounder, it is more preferred that the compounder has plural electron-donating groups.

With regard to the compounder, it is preferred that the compounder has at least one pi-electron system such as carbon-carbon double bond and carbon-oxygen double bond.

With regard to the compounder, it is preferred that such pi-electron system is connected to an aromatic ring. Furthermore, it is preferred that at least one electron-donating group on such aromatic ring is positioned at ortho- or para-position of such pi-electron system.

With regard to the compounder, it is preferred that the chemical species is at least one of acid and base.

With regard to the compounder, it is preferred that the chemical species is at least one of Brönsted acid and Brönsted base.

A composition relating to an aspect of the present invention includes: any one of the above compounders; and the precursor.

With regard to the composition, it is preferred that the composition further includes: a compound which is capable of polymerizing by the chemical species.

With regard to the composition, it is preferred that such compound has at least one epoxy group, at least one oxetanyl group or at least one ester group.

With regard to the composition, it is preferred that the composition further includes: a compound of which is capable of occurring by the chemical species.

With regard to the composition, it is preferred that the precursor is a photoacid generator (PAG).

A polymer relating to an aspect of the present invention includes: a first moiety capable of acting as a photosensitizing moiety; and a second moiety which is to react with a chemical species.

A typical example of such photosensitizing moiety is moiety having at least one aromatic ring and at least one electron-donating group such as alkoxy group, aryloxy group, amino group having at least one alkyl or aryl group on the nitrogen group, alkylthio group, arylthio group and trialkylsilylmethyl group.

It is preferred that such photosensitizing moiety has at least one aromatic ring. It is more preferable that at least one electron-donating group on such aromatic ring.

It is preferred that such photosensitizing moiety has a pi-electron system such as carbon-carbon double bond and carbon-oxygen double bond. It is more preferable that such pi-electron system is connected to an aromatic ring. Furthermore, it is preferred that at least one electron-donating group on such aromatic ring is positioned at ortho- or para-position of such pi-electron system.

A typical example of such second moiety is a moiety having epoxy group, oxetanyl group or ester group.

With regard to the polymer, it is preferred that typical examples of the chemical species acid and base.

With regard to the polymer, it is preferred that the polymer further includes: a third moiety which is to generate the chemical species. An example of such third moiety is a moiety having onium structure such as sulfonium and iodonium.

A method for manufacturing a device relating to an aspect of the present invention includes: applying at least one of any one of the above compositions and a solution of such composition to form a coating film such that a transmittance at 365 nm of the coating film is equal to or higher than 75%; and exposing the coating film to a light.

With regard to the method, it is preferred that the coating film is cured by the exposing of the coating film.

A method for manufacturing a device relating to an aspect of the present invention includes: applying at least one of any one of the above compositions and a solution of such composition to form a coating film; and exposing the coating film to a light to form a cured film such that a transmittance of the cured film is equal to or greater than 90%.

A method for manufacturing a device relating to an aspect of the present invention includes: applying at least one of any one of the above compositions and a solution of such composition to form a coating film such that a transmittance at 313 nm of the coating film is equal to or higher than 75%; and exposing the coating film to a light.

A method for manufacturing a device relating to an aspect of the present invention includes: applying at least one of any one of the above compositions and a solution of such composition to form a coating film such that a transmittance at 313 nm of the coating film is equal to or higher than 10% and a transmittance at 365 nm of the coating film is equal to or higher than 75%; and exposing the coating film to a light.

With regard to the method, it is preferred that the composition includes a compounder and a precursor; the compounder absorbs the light; and the precursor generates a chemical species.

With regard to the method, it is preferred that a formation of the chemical species from the precursor is enhanced by an interaction between the compounder and the precursor.

With regard to the method, it is preferred that: the compounder is excited by absorbing the light; and the excited compounder donates an electron to the precursor.

With regard to the method, it is preferred that the compounder has: an aromatic ring; and an electron-donating group on the aromatic ring.

With regard to the method, it is preferred that the compounder has a double bond.

With regard to the method, it is preferred that the coating film is cured to form a cured film by the exposing of the coating film.

With regard to the method, it is preferred that a transmittance of the cured film is equal to or greater than 90%.

With regard to the method, it is preferred that the cured film is an interlayer insulating film of the device.

With regard to the method, it is preferred that the method further includes: forming a pixel electrode above the cured film.

With regard to the method, it is preferred that an opening is formed in the cured film. The pixel electrode can be electrically connected through the opening to an active element such as transistor.

With regard to the method, it is preferred that the compounder has: a plurality of aromatic rings; and a plurality of electron-donating groups.

With regard to the method, it is preferred that the composition further includes a compound which is polymerized by the chemical species.

With regard to the method, it is preferred that a formation of the precursor is enhanced by an interaction between the compounder excited by the light and the precursor.

With regard to the method, it is preferred that the precursor received through the interaction between the compounder excited by the light and the precursor.

### BRIEF DESCRIPTION OF THE DRAWINGS

In the drawings, which illustrate what is currently considered to be the best mode for carrying out several aspects of the present invention:

FIG. 1 shows the structures of the patterned cured films.

FIG. 2A shows an exemplary fabrication process of a display device such as organic electroluminescent device (OLED) using a photoresist relating to an aspect of the present invention.

FIG. 2B shows an exemplary fabrication process of a display device such as organic electroluminescent device (OLED) using a photoresist relating to an aspect of the present invention.

FIG. 2C shows an exemplary fabrication process of a display device such as organic electroluminescent device (OLED) using a photoresist relating to an aspect of the present invention.

FIG. 2D shows an exemplary fabrication process of a display device such as organic electroluminescent device (OLED) using a photoresist relating to an aspect of the present invention.

FIG. 2E shows an exemplary fabrication process of a display device such as organic electroluminescent device (OLED) using a photoresist relating to an aspect of the present invention.

FIG. 2F shows an exemplary fabrication process of a display device such as organic electroluminescent device (OLED) using a photoresist relating to an aspect of the present invention.

FIG. 2G shows an exemplary fabrication process of a display device such as organic electroluminescent device (OLED) using a photoresist relating to an aspect of the present invention.

FIG. 2H shows an exemplary fabrication process of a display device such as organic electroluminescent device (OLED) using a photoresist relating to an aspect of the present invention.

FIG. 2I shows an exemplary fabrication process of a display device such as organic electroluminescent device (OLED) using a photoresist relating to an aspect of the present invention.

### DETAILED DESCRIPTION

### Experimental Procedures

### Synthesis of 2,2′,4,4′-tetramethoxybenzophenone (Compounder A)

2.00 g of 2,2′,4,4′-tetrahydroxybenzophenone 3.68 g of dimethyl sulfate and 4.03 g of potassium carbonate are dissolved in 12.0 g of acetone. The mixture is stirred at reflux temperature for 8 hours. Since then, the mixture is cooled to 25 degrees Celsius and it is further stirred 10 minutes after addition of 60.0 g of water and a deposit is filtrated. Then the deposit is dissolved in 20.0 g ethyl acetate and the organic phase is washed with water. Thereafter, ethyl acetate is distilled away, and the resultant is purified by recrystallization using 15.0 g of ethanol. Thereby 1.40 g of 2,2′,4,4′-tetramethoxybenzophenone is obtained.

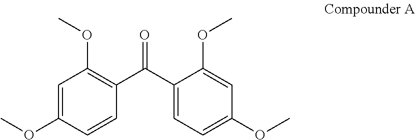

### Synthesis of 2,4-dimethoxy-4′-methoxy-benzophenone (Compounder B)

Synthesis of 2,4-dimethoxy-4′-methoxy-benzophenone as a target substance is synthesized and obtained according to the synthesis of Compounder A mentioned above, except for using 2,4-dimethoxy-4′-hydroxybenzophenone instead of 2,2′,4,4′-tetrahydroxybenzophenone for the synthesis of Compounder A.

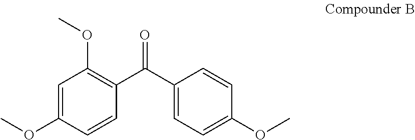

### Synthesis of 2,4-dimethoxy-4′-(2-vinyloxy-ethoxy)-benzophenone

2.00 g of 2, 4-dimethoxy-4′-hydroxybenzophenone, 2.48 g of 2-chloroethyl vinyl ether and 3.21 g of potassium carbonate are dissolved in 12.0 g of dimethyl formamide. The mixture is stirred at 110 degrees Celsius for 15 hours. Since then, the mixture is cooled to 25 degrees Celsius and it is further stirred after addition of 60.0 g of water. Then extracted with 24.0 g toluene and the organic phase is washed with water. Thereafter, toluene is distilled away. Thereby 3.59 g of 2,4-dimethoxy-4′-(2-vinyloxy-ethoxy)-benzophenone is obtained.

### Synthesis of 2,4-dimethoxy-4′-(2-hydroxy-ethoxy)-benzophenone

3.59 g of 2,4-dimethoxy-4′-(2-vinyloxy-ethoxy)-benzophenone, 0.28 g of pyridinium p-toluenesulfonate and 2.1 g of water are dissolved in 18.0 g of acetone. The mixture is stirred at 35 degrees Celsius for 12 hours. Since then, the mixture is further stirred after addition of 3% aqueous solution of sodium carbonate. Then extracted with 28.0 g ethyl acetate and the organic phase is washed with water. Thereafter, ethyl acetate is distilled away. Thereby 3.04 g of 2,4-dimethoxy-4′-(2-hydroxy-ethoxy)-benzophenone is obtained.

### Synthesis of {2-[2-(3-Ethyl-oxetan-3-ylmethoxycarbonylmethoxy)-4-methoxy-benzoyl]-5-methoxy-phenoxy}-acetic acid 3-ethyl-oxetan-3-ylmethyl ester (Compounder C)

3.0 g of 2,2′-dihydroxy-4,4′-dimethoxybenzophenone, 4.6 g of chloro-acetic acid 3-ethyl-oxetan-3-ylmethyl ester and 3.3 g of potassium carbonate are dissolved in 24 g of acetone. The mixture is stirred at reflux temperature for 8 hours. Since then, the mixture is cooled to 25 degrees Celsius and it is further stirred 10 minutes after addition of 60.0 g of water. Then extracted with 30 g ethyl acetate and the organic phase is washed with water. Thereafter, ethyl acetate is distilled away, and the residue is purified by silica gel column chromatography (ethyl acetate:hexane=3:7). Thereby 4.88 g of {2-[2-(3-Ethyl-oxetan-3-ylmethoxycarbonylmethoxy)-4-methoxy-benzoyl]-5-methoxy-phenoxy}-acetic acid 3-ethyl-oxetan-3-ylmethyl ester is obtained.

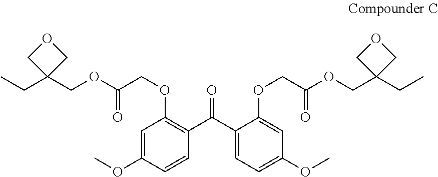 [SMILES: CCC1(COC(=O)COc2cc(OC)ccc2C(=O)c2ccc(OC)cc2OCC(=O)OCC2(CC)COC2)COC1]

### Synthesis of 2,4-dimethoxy-4′-(2-methacryloxy-ethyl)-benzophenone (Compounder D)

3.0 g of 2,4-dimethoxy-4′-(2-hydroxy-ethoxy)-benzophenone and 1.7 g of methacrylic anhydride are dissolved in 21 g of tetrahydrofuran. 1.2 g of triethylamine dissolved in 3.6 g of tetrahydrofuran is added dropwise to the tetrahydrofuran solution containing 2,4-dimethoxy-4′-(2-hydroxy-ethoxy)-benzophenone over 10 minutes. After that the mixture is stirred at 25 degrees Celsius for 3 hours. Since then, the mixture is further stirred after addition of water. Then extracted with 30 g ethyl acetate and the organic phase is washed with water. Thereafter, ethyl acetate is distilled away, and the residue is purified by silica gel column chromatography (ethyl acetate:hexane=1:9). Thereby 2.72 g of 2,4-dimethoxy-4′-(2-methacryloxy-ethyl)-benzophenone is obtained.

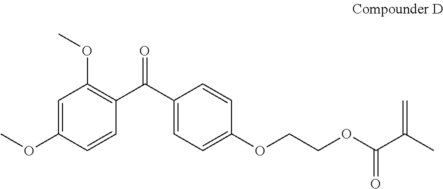 [SMILES: C=C(C)C(=O)OCCOc1ccc(C(=O)c2ccc(OC)cc2OC)cc1]

### Synthesis of 2-methyl-acrylic acid 2-(9-oxo-9H-thioxanthen-2-yloxy)-ethyl ester (Compounder E)

### Synthesis of 2-methyl-acrylic acid 2-(9-oxo-9H-thioxanthen-2-yloxy)-ethyl ester (Compounder E)

Synthesis of 2-methyl-acrylic acid 2-(9-oxo-9H-thioxanthen-2-yloxy)-ethyl ester as a target substance is synthesized and obtained according to the synthesis of Compounder D mentioned above, except for using 2-hydroxy-thioxanthen-9-one instead of 2,4-dimethoxy-4′-(2-hydroxy-ethoxy)-benzophenone for the synthesis of Compounder D.

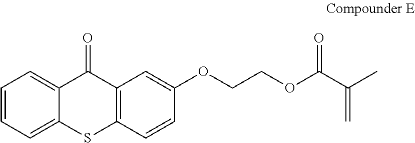 [SMILES: C=C(C)C(=O)OCCOc1ccc2sc3ccccc3c(=O)c2c1]

A solution containing 10.0 g of grycidyl methacrylate, 10.5 g of 2-ethyl hexyl methacrylate and 5.50 g of styrene, 1.22 g of dimethyl-2,2′-azobis(2-methylpropionate), and 25 g of Propylene glycol-1-Monomethyl Ether 2-Acetate (PGMEA) is prepared. The prepared solution is added dropwise over 4 hours to 8.7 g of PGMEA placed in flask with stirring and heating at 80 degrees Celsius. After the addition of the prepared solution, the mixture is heated to 80 degrees Celsius for 2 hours and cooled to a room temperature. Addition of the mixture by drops to a mixed liquid containing 220 g of hexane and 24 g of PGMEA with vigorously stirring precipitates the copolymer. The copolymer is isolated by filtration. Purification of the copolymer is carried out by vacuum drying following twice washings by 78 g of hexane, and thereby 11.3 g of white powder of the copolymer is obtained.

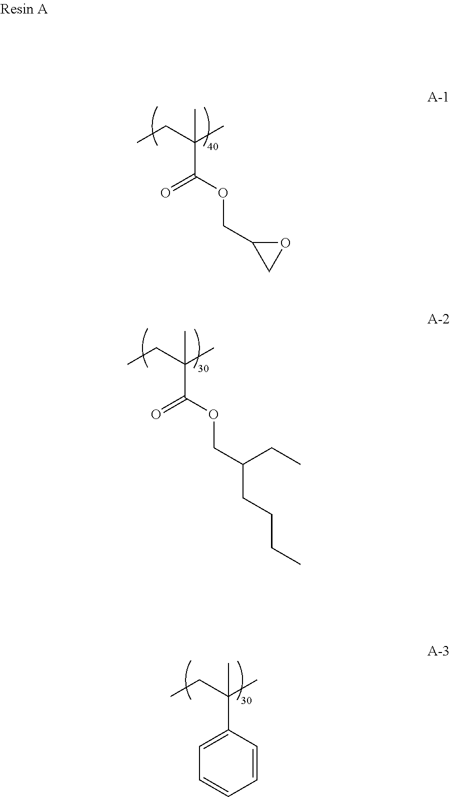

A solution containing 10.0 g of grycidyl methacrylate, 6.3 g of 2-ethyl hexyl methacrylate, 1.9 g of methacrylic acid 3-ethyl-oxetan-3-ylmethyl ester and 6.3 g of styrene, 1.39 g of dimethyl-2,2′-azobis(2-methylpropionate), and 30 g of Propylene glycol-1-Monomethyl Ether 2-Acetate (PGMEA) is prepared. The prepared solution is added dropwise over 4 hours to 10 g of PGMEA placed in flask with stirring and heating at 80 degrees Celsius. After the addition of the prepared solution, the mixture is heated to 80 degrees Celsius for 2 hours and cooled to a room temperature. Addition of the mixture by drops to a mixed liquid containing 260 g of hexane and 29 g of PGMEA with vigorously stirring precipitates the copolymer. The copolymer is isolated by filtration. Purification of the copolymer is carried out by vacuum drying following twice washings by 90 g of hexane, and thereby 12.6 g of white powder of the copolymer is obtained.

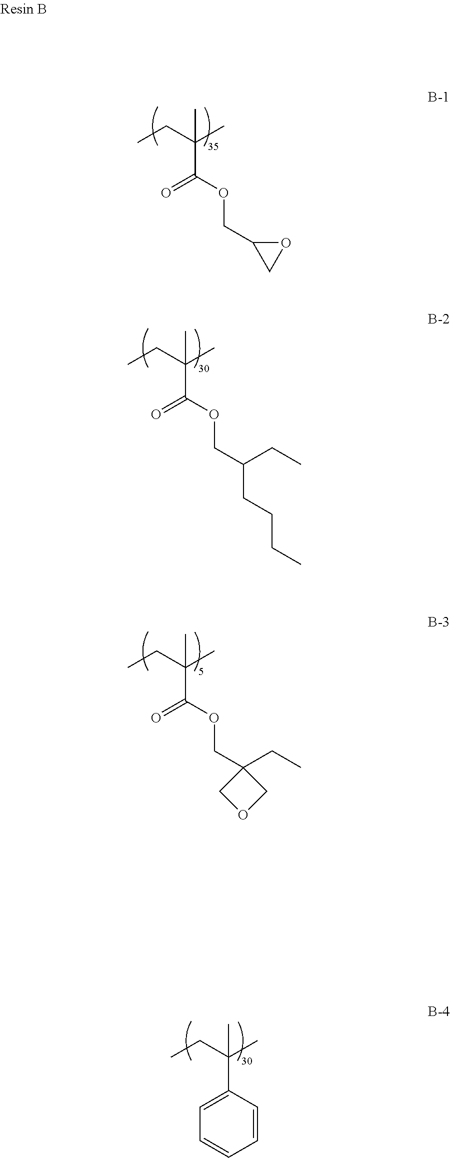

A solution containing 10.0 g of grycidyl methacrylate, 6.3 g of 2-ethyl hexyl methacrylate, 1.9 g of methacrylic acid 3-ethyl-oxetan-3-ylmethyl ester, 6.3 g of styrene and 0.23 g of 2,4-dimethoxy-4′-(2-methacryloxy-ethyl)-benzophenone, 1.39 g of dimethyl-2,2′-azobis(2-methylpropionate), and 30 g of Propylene glycol-1-Monomethyl Ether 2-Acetate (PGMEA) is prepared. The prepared solution is added dropwise over 4 hours to 10 g of PGMEA placed in flask with stirring and heating at 80 degrees Celsius. After the addition of the prepared solution, the mixture is heated to 80 degrees Celsius for 2 hours and cooled to room temperature. Addition of the mixture by drops to a mixed liquid containing 260 g of hexane and 29 g of PGMEA with vigorously stirring precipitates the copolymer. The copolymer is isolated by filtration. Purification of the copolymer is carried out by vacuum drying following twice washings by 90 g of hexane, and thereby 12.4 g of white powder of the copolymer is obtained.

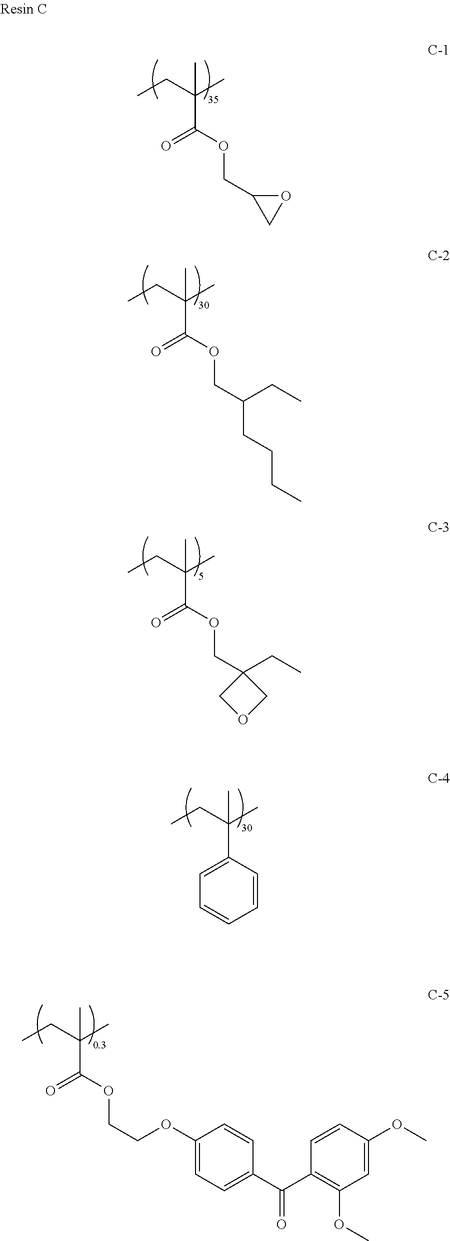

A solution containing 10.0 g of grycidyl methacrylate, 6.3 g of 2-ethyl hexyl methacrylate, 1.9 g of methacrylic acid 3-ethyl-oxetan-3-ylmethyl ester, 6.3 g of styrene and 0.20 g of 2-methyl-acrylic acid 2-(9-oxo-9H-thioxanthen-2-yloxy)-ethyl ester 1.39 g of dimethyl-2,2′-azobis(2-methylpropionate), and 30 g of Propylene glycol-1-Monomethyl Ether 2-Acetate (PGMEA) is prepared. The prepared solution is added dropwise over 4 hours to 10 g of PGMEA placed in flask with stirring and heating at 80 degrees Celsius. After the addition of the prepared solution, the mixture is heated to 80 degrees Celsius for 2 hours and cooled to room temperature. Addition of the mixture by drops to a mixed liquid containing 260 g of hexane and 29 g of PGMEA with vigorously stirring precipitates the copolymer. The copolymer is isolated by filtration. Purification of the copolymer is carried out by vacuum drying following twice washings by 90 g of hexane, and thereby 12.6 g of white powder of the copolymer is obtained.

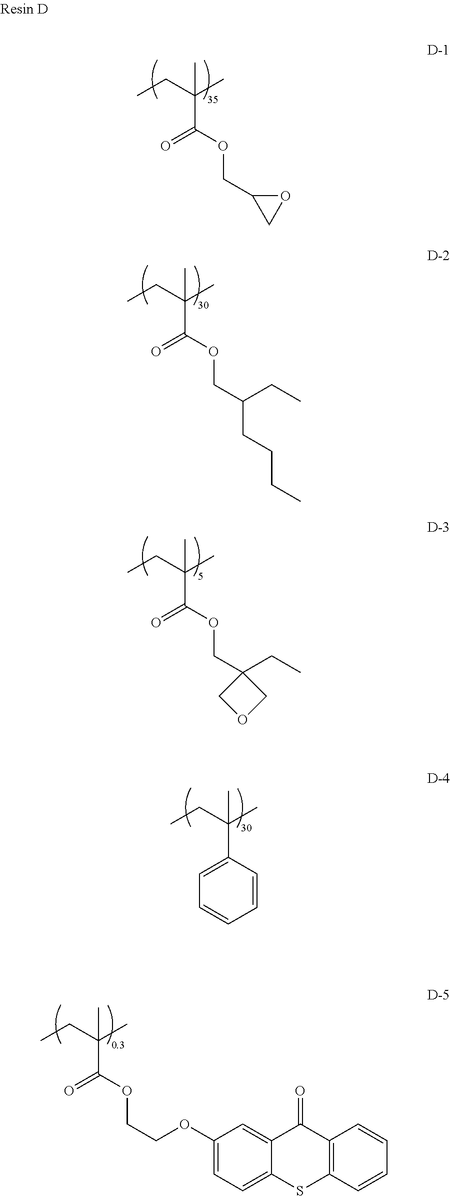

### Preparation of Samples for Evaluation (the “Evaluation Samples”)

Evaluation Samples 1-45 are prepared by dissolving in 600 mg of cyclohexanone (i) 0.010 mmol of a PAG selected from a group of consisting of phenyl dibenzothionium hexafluoroantimonate (PBpS-SbF₆), diphenyl 4-thiophenoxy-phenyl sulfonium hexafluoroantimonate (PSDPS-SbF₆), diphenyliodonium hexafluoroantimonate (DPI-SbF₆) and di-4-tert-butyl phenyliodonium hexafluoroantimonate (TBDPI-SbF₆) (ii) 400 mg of a resin selected from a group consisting of Resins A, B, C, D and cresol novolac type epoxy resin (Resin E) and (iii) at least 0.010 mmol of one additive selected from a group consisting of Compounders mentioned above or 0.005 mmol of 2-isopropylthioxanthen-9-one (IPTX), or (iv) 0 mmol of additive and (v) 20 mg of trimethylpropane triglycidyl ether as a cross-linker.

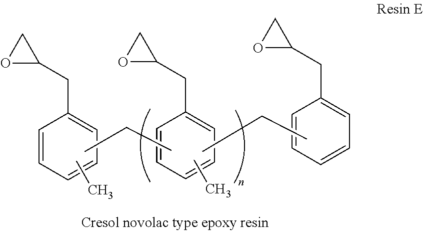

Table 1 shows detail of sample compositions.

TABLE 1
Evaluation Samples for evaluation for efficiencies of patterning

| | Resin | PAG | Additive | Cross linker | Exposure condition |
|---|---|---|---|---|---|
| Evaluation Sample 1 | Resin A | PBpS-SbF₆ | — | added | with cut-off filter |
| Evaluation Sample 2 | | | | | without cut-off filter |
| Evaluation Sample 3 | | | Compounder A | | with cut-off filter |
| Evaluation Sample 4 | | | | — | |
| Evaluation Sample 5 | | | | added | without cut-off filter |
| Evaluation Sample 6 | | | Compounder B | | with cut-off filter |
| Evaluation Sample 7 | | | Compounder C | | |
| Evaluation Sample 8 | | | IPTx | — | |
| Evaluation Sample 9 | | | | added | |
| Evaluation Sample 10 | | PSDPS-SbF₆ | — | added | |
| Evaluation Sample 11 | | | | | without cut-off filter |
| Evaluation Sample 12 | | | Compounder A | | with cut-off filter |
| Evaluation Sample 13 | | | | | without cut-off filter |
| Evaluation Sample 14 | | | Compounder B | | with cut-off filter |
| Evaluation Sample 15 | | | Compounder C | | |
| Evaluation Sample 16 | | | IPTx | | |
| Evaluation Sample 17 | | | | | without cut-off filter |
| Evaluation Sample 19 | | DPI-SbF₆ | | | without cut-off filter |
| Evaluation Sample 20 | | | Compounder A | | with cut-off filter |
| Evaluation Sample 21 | | | Compounder B | | |
| Evaluation Sample 22 | | | Compounder C | | |
| Evaluation Sample 24 | | DTBPI-SbF₆ | | | without cut-off filter |
| Evaluation Sample 25 | | | Compounder A | | with cut-off filter |
| Evaluation Sample 26 | | | Compounder B | | |
| Evaluation Sample 27 | | | Compounder C | | |
| Evaluation Sample 28 | Resin B | PBpS-SbF₆ | Compounder A | | |
| Evaluation Sample 29 | | PSDPS-SbF₆ | | | |
| Evaluation Sample 30 | | DPI-SbF₆ | | | |
| Evaluation Sample 31 | | DTBPI-SbF₆ | | | |
| Evaluation Sample 32 | Resin C | PBpS-SbF₆ | — | | |
| Evaluation Sample 33 | | PSDPS-SbF₆ | | | |
| Evaluation Sample 34 | | DPI-SbF₆ | | | |
| Evaluation Sample 35 | | DTBI-SbF₆ | | | |
| Evaluation Sample 36 | Resin D | PBpS-SbF₆ | — | | |
| Evaluation Sample 37 | | PSDPS-SbF₆ | | | |
| Evaluation Sample 38 | | DPI-SbF₆ | | | |
| Evaluation Sample 39 | | DTBPI-SbF₆ | | | |
| Evaluation Sample 40 | Resin E | PBpS-SbF₆ | — | | |
| Evaluation Sample 41 | | | | | without cut-off filter |
| Evaluation Sample 42 | | | Compounder A | | |
| Evaluation Sample 43 | | PSDPS-SbF₆ | | | with cut-off filter |
| Evaluation Sample 44 | | DPI-SbF₆ | | | |
| Evaluation Sample 45 | | DTBPI-SbF₆ | | | |

### Evaluation of Sensitivity

Before applying each of Evaluation Samples to a Si wafer, hexamethyldisilazane (HMDS, Tokyo Chemical Industry) is spin-coated on the surface of the Si wafer and baked at 110 degrees Celsius for 5 minutes. Then, each of Evaluation Samples is spin-coated on the surface of the Si wafer which has been treated with HMDS at 2000 rpm for 20 seconds to form a coating film. The prebake of the coating film is performed at 110 degrees Celsius for 60 seconds. Then the coating film of each of Evaluation Samples is exposed to a light emitted from an UV exposure system (HMW-661C-3 ORC manufacturing Co. LTD.). The light has an emission spectrum with an emission line at 313 nm and another emission line at 365 nm. In several cases, the emission line at 313 nm is cut off by UV cut-off filter (Colored optical glass UV-340 HOYA Co. LTD.) After that the UV light exposure, a post-exposure-bake (PEB) is carried out at 110 degrees Celsius for 10 minutes. The coating film is developed with γ-butyrolactone for 1 minute at 25 degrees Celsius and rinsed with deionized water for 1 minute. The thickness of the coating film measured using film thickness measurement tool is approximately 15 μm. Thereafter, a sensitivity (Eₘₐₓ sensitivity) is evaluated by measuring the dose size to form a pattern constituted by 100 μm lines where the thickness of the coating film is not zero and 100 μm spaces where the thickness of the coating film is zero using UV exposure system, and dose for Eₘₐₓ sensitivity is calculated by means of a measurement of illuminance of UV source by 365 nm illuminometer (USHIO UIT-150, UVD-S365).

### Evaluation of Visible Light Transmittance

Each of Evaluation Samples is spin-coated on a surface of a quartz wafer to form a coating film. The prebake of the coating film is performed at 110 degrees Celsius for 5 minutes. The thickness of the coating film measured using film thickness measurement tool is approximately 15 μm. Then the transmittance of the coating film is measured for each of Evaluation Samples by ultraviolet-visible spectroscopy to evaluate before UV light irradiation of the coating film is carried out. Thereafter, the coating film of the Evaluation Sample is exposed to a UV light output from an UV exposure system (HMW-661C-3 ORC manufacturing Co. LTD.) of which intensity is twice higher than Eₘₐₓ sensitivity which has been estimated by the sensitivity evaluation explained above. A light containing emission lines at 313 nm and 365 nm or a light in which the emission line at 313 nm is cut off by UV cut-off filter (Colored optical glass UV-340 HOYA Co. LTD.) is used as the UV light.

### Evaluation of Surface Hardness of Resin

Each of Evaluation Samples is spin-coated on the surface of a Si wafer to form a coating film. The prebake of the coating film is performed at 110 degrees Celsius for 5 minutes. The thickness of the coating film measured using film thickness measurement tool is approximately 15 μm. Then the coating film of the Evaluation Sample is exposed to same as dose of Eₘₐₓ sensitivity using a ultraviolet (UV) light having an emission spectrum with two emission lines at 313 nm and 365 nm (i-line) or in which the emission line at 313 nm is cut off by UV cut-off filter (Colored optical glass UV-340 HOYA Co. LTD.) between the two emission lines by light. After that the UV light exposure, a post-exposure-bake (PEB) is carried out at 110 degrees Celsius for 10 minutes to form a cured film. Then, surface hardness for each of Evaluation Samples is measured by pencil hardness test method. If the pencil hardness of the cured film is equal to or greater than 3H from the hardness test, the cured film is judged to be of good hardness as an interlayer insulator film. Doses are calculated by means of a measurement of illuminance of UV source by 365 nm illuminometer (USHIO UIT-150, UVD-S365).

Table 2 shows the dose sizes corresponding to Eₘₐₓ sensitivities, transmittances and pattern shape measured for the Evaluation Samples 1 to 45.

For Evaluation Samples 1, 19, 24 and 40, formation of acid by an irradiation by i-line UV exposure is not observed under the condition explained above. The Eₘₐₓ sensitivities are high for Evaluation Samples containing Compounder A, which has the highest electron-donating ability among Compounder A, B and C because Compounder A has most electron-donating groups than Compounders B and C. The Eₘₐₓ sensitivities are high for Evaluation Samples containing Compounder B, which has higher electron-donating ability than Compounder C. Thioxanthone derivatives such as IPTx and D-5 moiety have higher molar absorption coefficient at wavelength equal to or longer than 365 nm.

Formation of acid by the light irradiation without cut filter is observed for Evaluation Samples 2 despite the absence of any sensitizers. This indicates that acid generation occurs from the excitation of PBpS-SbF₆ with the emission line at 313 nm.

Formation of acid by the light irradiation with cut filter is observed for Evaluation Samples 10 despite the absence of any sensitizers. This indicates that acid generation occurs from the excitation of PSDPS-SbF₆ with both emission lines at 313 nm and 365 nm.

Tapered pattern structure of the cured film which gradually narrows from the surface of the cure film toward the surface of the Si wafer is observed for each of Evaluation Samples 11 and 41. In other words, the curing efficiency of the coating film decreases from the surface of the cure film toward the surface of the Si wafer.

Coating films of Evaluation Samples 11 and 41 are irradiated with the light including the emission line at 313 nm where each of Evaluation Samples 11 and 41 have a strong absorbance because the irradiations are carried out without a cut-off filter. The component with the wavelength of 313 nm of the light is mainly absorbed in the vicinity of the surface of the coating films. Evaluation Samples 11 and 41 have a less strong absorbance at 365 nm compared to 313 nm although the component with the wavelength of 365 is likely to reach the surface of the Si wafer.

Therefore, portions of the coating films close to the surface of the Si wafer are unlikely to be cured.

The addition of sensitizer can reverses the narrowing of the cured film toward the surface of the Si wafer.

Patterned structures of cured films of Evaluation Samples 5, 13 and 17 each of which contains a sensitizer in addition to PAG are observed to have rectangle structures although irradiation UV exposures are carried out without any cut-off filter. In other words, the sensitizer compensates for decrease of efficiency of acid generation with the depth of the coating film.

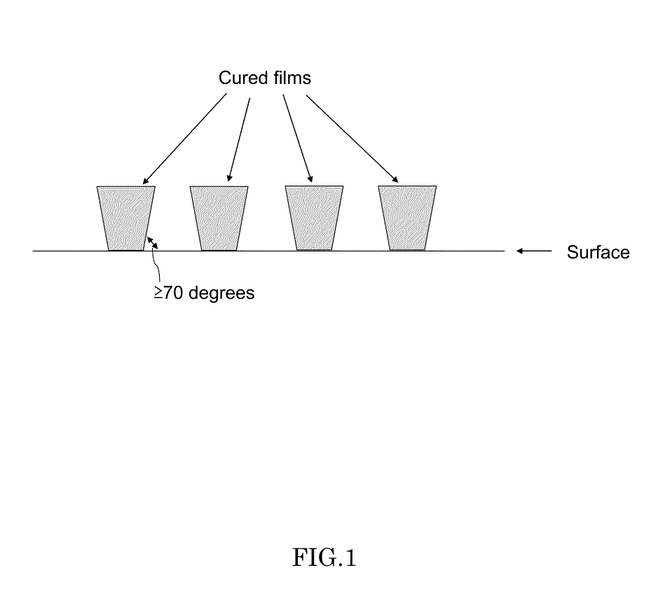

As shown in FIG. 1, it is preferred that an angle between the surface of the substrate and the surface of the cured film is equal to or greater than 70 degrees. It is preferred that the angle is equal to or greater than 70 degrees and smaller than 90 degrees. More preferably, the angle is equal to or greater than 80 degrees and smaller than 90 degrees.

An incorporation C-5 moieties acting as photosensitizers into polymer enables homogeneous dispersion of the photosensitizers, which can improve of acid generation efficiency.

The transmittance at 400 nm is lower for Evaluation Sample 9, 16, 17, 36-39 containing the moiety of thioxanthone compared to Compounders A to C. In other words, Compounders A to C have significantly high transparency in the visible light region, which means Compounders A to C are more suitable for optical device in which a visible light propagates a long distance such as light waveguide, optical fiber and electro-optical device

The film hardness is high for Evaluation Samples containing trimethylpropane triglycidyl ether as a cross-linker compared to resins containing epoxide or oxetane moiety. This indicates that the trimethylpropane triglycidyl ether contributes higher cross-linking ability.

Since the molecular size of trimethylpropane triglycidyl ether is small compared to such resin, the molecules of trimethylpropane triglycidyl ether can move much easier than such resin. Therefore cross-linking densities of cured films which contains trimethylpropane triglycidyl ether are higher.

The film hardness is high for Evaluation Samples containing Compounder C, which has oxetane moieties in addition to the photosensitizing moiety, despite the absence of cross linker. This indicates that the oxetane moieties of Compounder C contribute the improvement of the cross-linking density of the cured films.

TABLE 2
The doses for Eₘₐₓ by UV exposure, film transmittances and film hardness of cured films formed from Evaluation Samples

| | | Trancemittance | Trancemittance | Trancemittance | Trancemittance | | |
|---|---|---|---|---|---|---|---|
| | Dose for Eₘₐₓ | at 313 nm before | at 365 nm before | at 400 nm before | at 400 nm after | | |
| | Dose at 365 nm | exposure about | exposure about | exposure about | exposure about | | Pencil |
| | [mJ/cm²] | 15 μm film | 15 μm film | 15 μm film | 15 μm film | Pattern shape | hardness test |
| Evaluation Sample 1 | >5000 | 89.2 | >99.5 | >99.5 | >99.5 | No pattern | — |
| Evaluation Sample 2 | 2350 | | | | | Rectangle | 6H |
| Evaluation Sample 3 | 420 | 56.2 | 97.1 | | | | 6H |
| Evaluation Sample 4 | 440 | 56.1 | 97.1 | | | | 4H |
| Evaluation Sample 5 | 340 | 56.2 | 97.1 | | | | 6H |
| Evaluation Sample 6 | 550 | 65.8 | 98.5 | | | | 6H |
| Evaluation Sample 7 | 500 | 59.2 | 97.4 | | | | 6H |
| Evaluation Sample 8 | 500 | 59.2 | 97.3 | | | | 5H |
| Evaluation Sample 9 | 250 | 88.8 | 90.1 | 91.2 | 98.3 | | 6H |
| Evaluation Sample 10 | 240 | 66.9 | 98.9 | >99.5 | >99.5 | | 6H |
| Evaluation Sample 11 | 160 | | | | | Tapered | 6H |
| Evaluation Sample 12 | 160 | 37.1 | 96.1 | | | Rectangle | 6H |
| Evaluation Sample 13 | 120 | | | | | | 6H |
| Evaluation Sample 14 | 210 | 46.2 | 97.4 | | | | 6H |
| Evaluation Sample 15 | 190 | 39.9 | 96.5 | | | | 6H |
| Evaluation Sample 16 | 200 | 53.8 | 89.7 | 91.0 | 98.2 | | 6H |
| Evaluation Sample 17 | 140 | | | | 96.6 | | 6H |
| Evaluation Sample 19 | >5000 | 98.9 | >99.5 | >99.5 | >99.5 | No pattern | 6H |
| Evaluation Sample 20 | 430 | 66.2 | | | | Rectangle | 6H |
| Evaluation Sample 21 | 550 | 73.9 | | | | | 6H |
| Evaluation Sample 22 | 490 | 70.1 | | | | | 6H |
| Evaluation Sample 24 | >5000 | 98.6 | | | | No pattern | — |
| Evaluation Sample 25 | 650 | 66.0 | | | | Rectangle | 6H |
| Evaluation Sample 26 | 820 | 73.4 | | | | | 6H |
| Evaluation Sample 27 | 730 | 70.0 | | | | | 6H |
| Evaluation Sample 28 | 370 | 89.1 | 97.3 | | | | 6H |
| Evaluation Sample 29 | 140 | 37.3 | 96.2 | | | | 6H |
| Evaluation Sample 30 | 370 | 66.2 | >99.5 | | | | 6H |
| Evaluation Sample 31 | 570 | 66.1 | | | | | 6H |
| Evaluation Sample 32 | 500 | 66.1 | 98.7 | | | | 6H |
| Evaluation Sample 33 | 200 | 47.0 | 98.1 | | | | 6H |
| Evaluation Sample 34 | 510 | 74.3 | >99.5 | | | | 6H |
| Evaluation Sample 35 | 750 | 74.0 | | | | | 6H |
| Evaluation Sample 36 | 210 | 74.1 | 90.2 | 88.1 | 95.9 | | 6H |
| Evaluation Sample 37 | 170 | 59.3 | 88.8 | 88.0 | 95.7 | | 6H |
| Evaluation Sample 38 | 220 | 86.3 | >99.5 | >99.5 | >99.5 | | 6H |
| Evaluation Sample 39 | 320 | 86.0 | | | | | 6H |
| Evaluation Sample 40 | >5000 | 70.2 | | | | No pattern | — |
| Evaluation Sample 41 | 3300 | | | | | Tapered | 6H |
| Evaluation Sample 42 | 410 | 44.6 | 96.9 | | | Rectangle | 6H |
| Evaluation Sample 43 | 200 | 19.3 | 97.3 | | | | 6H |
| Evaluation Sample 44 | 520 | 84.0 | >99.5 | | | | 6H |
| Evaluation Sample 45 | 790 | 83.7 | | | | | 6H |

Each of Compounders F, G, H and their derivatives can be also preferably used as a photosensitizer. Each of the Compounders has electron donating character.

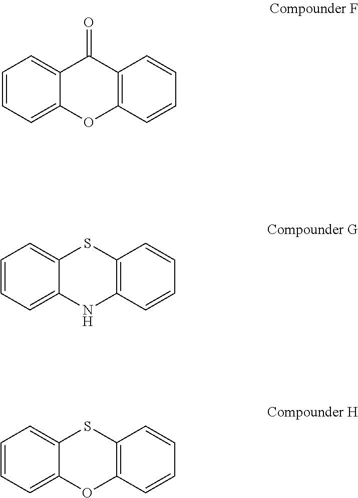 [SMILES: O=c1c2ccccc2oc2ccccc12 ; c1ccc2c(c1)Nc1ccccc1S2 ; c1ccc2c(c1)Oc1ccccc1S2]

Compounder A and Compounder B exhibit little absorption at wavelength longer than 400 nm. Therefore, Compounder A and Compounder B are especially suitable for photosensitizers enhancing generation of acid from PAG contained in a photoresist applicable to fabrication of an interlayer insulating film of electro-optical device such as liquid crystal device, organic electroluminescent device and optical communication device.

Compounder A or Compounder B are also useful for a constituent of material forming an interlayer insulating film of such electro-optical device because Compounder A and Compounder B hardly absorb a light of which wavelength is longer than 400 nm, which is desired to pass through the interlayer insulating film for display and optical communication cable.

If a substance which can acts as a photosensitizer or PAG by absorbing such visible light remains in an interlayer insulating film, acid is generated even during normal operations and deteriorates such electro-optical device.

Typically, the transmittance at 400 nm of cured film relating to an aspect of the present invention is equal to or higher than 90%. It is preferred that the transmittance at 400 nm of the cured film is equal to or higher than 95%. More preferably, the transmittance at 400 nm of film is equal to or higher than 98%.

Typically, the transmittance at 365 nm of coating films relating to an aspect of the present invention is equal to or higher than 75% before UV exposure. It is preferred that the transmittance at 365 nm of the coating films is equal to or higher than 85% before UV exposure. More preferably, the transmittance at 365 nm of the coating films is equal to or higher than 90% before UV exposure.

The transmittance at 313 nm of coating films relating to an aspect of the present is equal to or higher than 75% before UV exposure. It is preferred that the transmittance at 313 nm of the coating films is equal to or higher than 85% before UV exposure. More preferably, the transmittance at 313 nm of the coating films is equal to or higher than 90% before UV exposure.

The transmittance at 313 nm of coating films relating to an aspect of the present invention is equal to or higher than 10% before UV exposure as long as the transmittance at 365 nm of the coating films is equal to or higher than 75%. It is preferred that the transmittance at 313 nm of the coating films is equal to or higher than 50% before UV exposure as long as the transmittance at 365 nm of the coating films is equal to or higher than 75%. More preferably, the transmittance at 313 nm of the coating films is equal to or higher than 75% before UV exposure as long as the transmittance at 365 nm of the coating films is equal to or higher than 75%.

A typical ratio of the transmittance at 365 nm to transmittance at 400 nm in a coating film is equal to or greater than 0.9. A preferable ratio of transmittance at 365 nm to transmittance at 400 nm in a coating film is equal to or greater than 1.1. A more preferable ratio of transmittance at 365 nm to transmittance at 400 nm in a coating film is equal to or greater than 1.3

A ratio of the transmittance at 313 nm to the transmittance at 365 nm in a coating film is equal to or greater than 0.75. A preferable ratio of the transmittance at 313 nm to transmittance at 365 nm in a coating film is equal to or greater than 0.85. A more preferable ratio of the transmittance at 313 nm to the transmittance at 365 nm in a film is equal to or greater than 0.95.

A ratio of the transmittance at 313 nm to the transmittance at 365 nm in a coating film is equal to or greater than 0.75. A preferable ratio of the transmittance at 313 nm to the transmittance at 365 nm in a coating film is equal to or greater than 0.9. A more preferable ratio of the transmittance at 313 nm to the transmittance at 365 nm in a coating film is equal to or greater than 1.1.

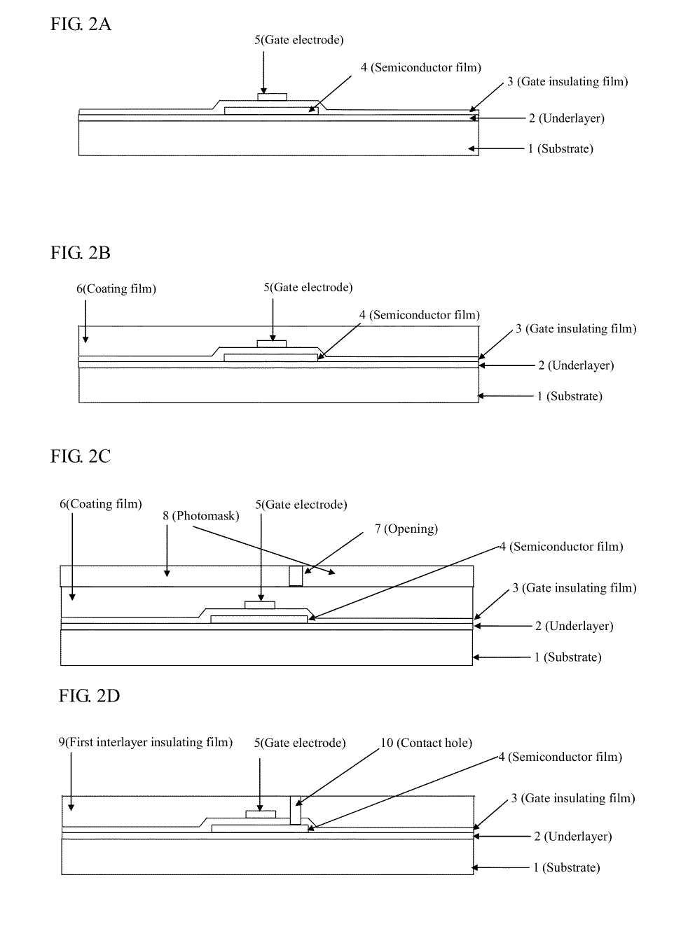

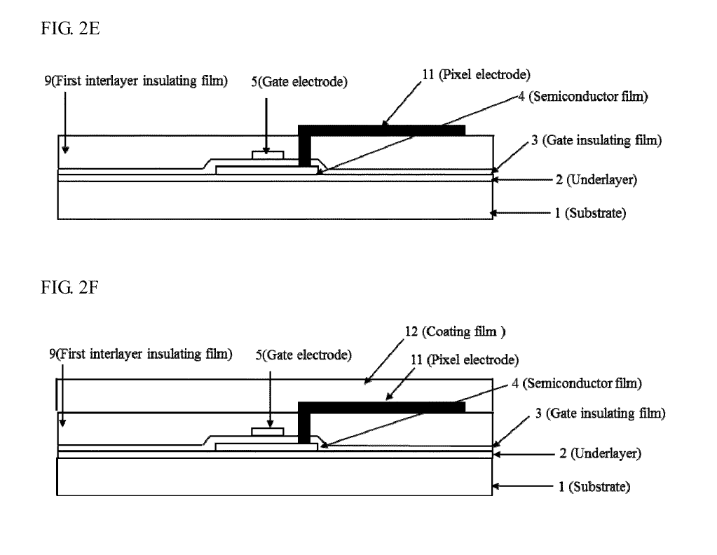

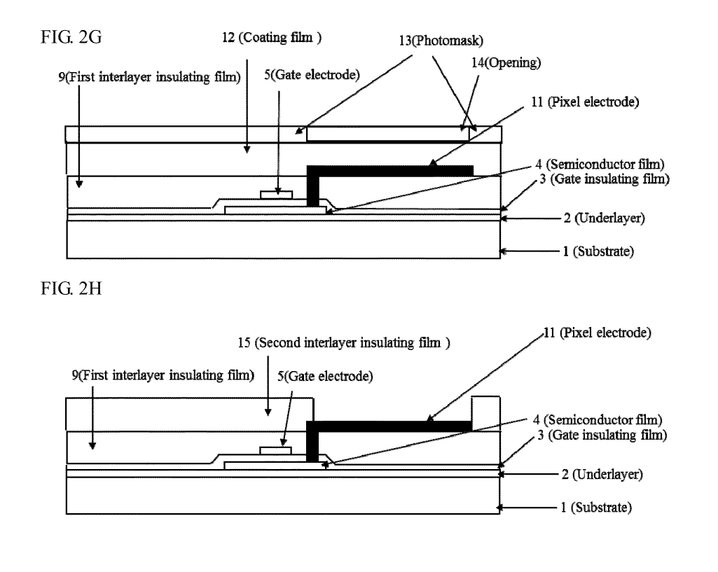

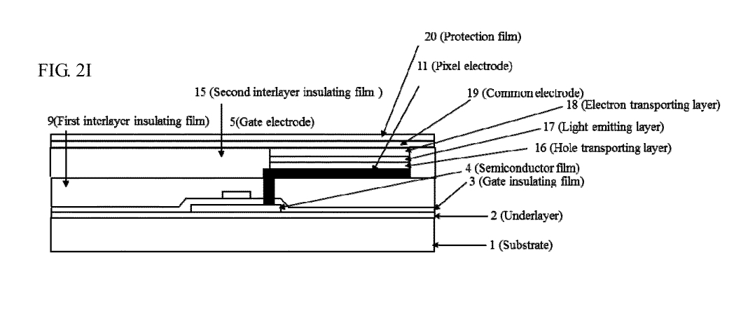

FIG. 2 shows fabrication processes for active matrix-type organic electroluminescent device.

(a) Underlayer 2 is formed on a Substrate 1 such as glass substrate, quartz substrate and plastic substrate. Semiconductor film 4 which is formed by patterning is formed on Underlayer 2. Typically, Semiconductor film 4 is made of low-temperature polysilicon. Amorphous silicon or metal oxide can also be used as material for Semiconductor film 4. Gate insulating film 3 is formed such that Gate insulating film 3 covers Semiconductor film 4. Gate electrode 5 is formed over Gate insulating film 3 such that Gate electrode 5 and Semiconductor film 4 face each other across Gate insulating film 3.

(b) Coating film 6 is disposed by spin-coating of a composition containing Resin F such that Coating film 6 covers Gate electrode 5 and Gate insulating film 3.

The moiety F-1 is excited by an irradiation of Coating film 6 with a light. The exited F-1 donates an electron to the moiety F-5. In other words, the moiety F-1 can act as a photosensitizer. The moiety F-5 generates acid by receiving the electron from the moiety F-1. Since the moieties F-1 and F-5 are in identical molecule, such electron transfer from F-1 to F-5 promptly occurs. The generated acid polymerizes the moiety F-2, which has an epoxy group. According to circumstances, compounder which can act as photosensitizer in its own such as Compounder A and Compounder B can be further contained in the composition.

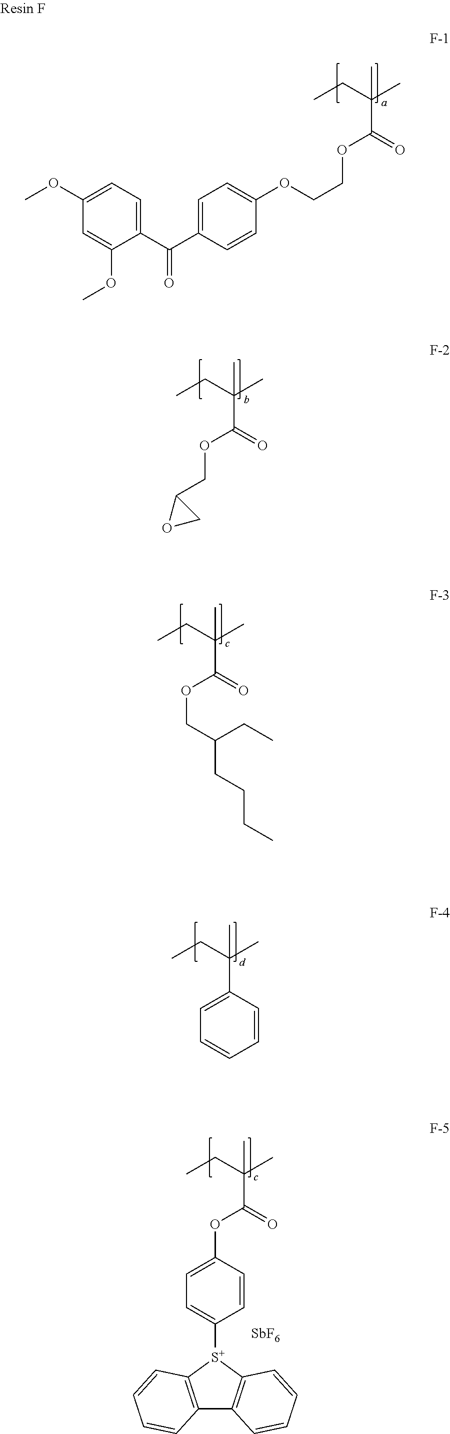

(c) Coating film 6 is irradiated with a light of which wavelength is 365 nm through Photomask 8 after Coating film 6 is subjected to prebake treatment. Only a portion of Coating film 6 is exposed to a light passing through Opening 7.

(d) The exposed portion of Coating film 6 by the light is removed by development to form Contact hole 10. Coating film 6 is converted into First interlayer insulating film 9 by a heat treatment carried out at a temperature higher than 150 degrees centigrade following formation of Contact hole 6.

(e) Pixel electrode 11 which is electrically connected to Semiconductor film 4 is formed. Typically, Pixel electrode 11 is made of Indium Tin Oxide (ITO) or magnesium-silver alloy.

(f) Coating film 12 is disposed by spin-coating process such that Coating film 12 covers Pixel electrode 11 and First interlayer insulating film 9.

(g) Coating film 12 is irradiated with a light of which wavelength 365 nm through Photomask 13 after Coating film 12 is subjected to prebake treatment. Only a portion of Coating film 12 is exposed to a light passing through Opening 14.

(h) The exposed portion of Coating film 12 by the light is removed by development. Coating film 12 is converted into Second interlayer insulating film 15 by a heat treatment carried out at a temperature higher than 150 degrees centigrade following removal of the exposed portion of Coating film 12.

(i) Hole transport layer 16, Light emitting layer 17 and Electron transporting layer 18 are formed by vacuum vapor deposition via mask in this order. Common electrode 19 is formed over Electron transporting layer 18 and Second interlayer insulating film 15. Protection film 20 is formed over Common electrode 19.

What is claimed is:

1. A method for manufacturing a device, comprising:
applying at least one of a composition and a solution of the composition to form a coating film such that a transmittance at 365 nm of the coating film is equal to or higher than 75%; and
exposing the coating film to a light.

2. The method of claim 1, wherein, the composition includes a compounder and a precursor;
the compounder absorbs the light; and
the precursor generates a chemical species.

3. The method of claim 2, wherein a formation of the chemical species from the precursor is enhanced by an interaction between the compounder and the precursor.

4. The method of claim 2, wherein the compounder is excited by absorbing the light and the excited compounder donates an electron to the precursor.

5. The method of claim 2, wherein the compounder has an aromatic ring and an electron-donating group on the aromatic ring.

6. The method of claim 2, wherein the compounder has a double bond.

7. The method of claim 1, wherein the coating film is cured to form a cured film by the exposing of the coating film.

8. The method of claim 7, wherein a transmittance of the cured film is equal to or greater than 90%.

9. The method of claim 8, wherein the cured film is an interlayer insulating film of the device.

10. The method of claim 8, further comprising:
forming a pixel electrode above the cured film.

11. The method of claim 7, wherein an opening is formed in the cured film.

12. The method of claim 2, wherein the compounder has a plurality of aromatic rings and a plurality of electron-donating groups.

13. The method of claim 2, wherein the composition further includes a compound which is polymerized by the chemical species.

14. The method of claim 2, wherein a formation of the precursor is enhanced by an interaction between the compounder excited by the light and the precursor.

15. The method of claim 14, wherein the precursor received through the interaction between the compounder excited by the light and the precursor.

16. The method of claim 10, further comprising:
forming an active element; and
connecting electrically the active element to the pixel electrode.

17. The method of claim 16, wherein the cured film is formed such that an opening is formed in the cured film for the electrically connecting of the active element to the pixel electrode.

18. A compounder for enhancing generation of chemical species, comprising:
a coating film exposed to a light and formed by at least one of a composition and a solution such that a transmittance at 365 nm of the coating film is equal to or higher than 75%;
wherein the composition includes a compounder and a precursor;
the compounder absorbs the light; and
the precursor generates a chemical species.

19. A system for manufacturing a device, the system comprising:
means for applying at least one of a composition and a solution of the composition to form a coating film such that a transmittance at 365 nm of the coating film is equal to or higher than 75%; and
means for exposing the coating film to a light.
